(19) United States
(12) Patent Application Publication
(10) Pub. No.: US 2026/0114065 A1
(43) Pub. Date: Apr. 23, 2026

(54) IMAGE SENSOR

(71) Applicant: VisEra Technologies Company Ltd., Hsin-Chu City (TW)

(72) Inventors: Chun-Yuan WANG, Hsin-Chu City (TW); Po-Hsiang WANG, Hsin-Chu City (TW)

(21) Appl. No.: 18/918,154

(22) Filed: Oct. 17, 2024

(51) Int. Cl. H01L 27/146

(52) U.S. Cl. CPC H10F 39/806; H10F 39/182; H10F 39/8053

(57) ABSTRACT

This disclosure provides an image sensor including two first color filters corresponding to a first wavelength band, a second color filter corresponding to a second wavelength band, and a third color filter corresponding to a third wavelength band arranged in a color filter array; and a plurality of nano-light pillars above the color filter array. The nano-light pillars include two first nano-light pillars within each first color filter, two second nano-light pillars and a third nano-light pillar on each boundary line between the first color filters and the second color filter, four fourth nano-light pillars within the second color filter, and a fifth nano-light pillar within the third color filter. The dimensions of the fourth nano-light pillars and the fifth nano-light pillar are larger than dimensions of the first nano-light pillars, the second nano-light pillars, and the third nano-light pillar.

### BACKGROUND

### Field of Invention

The present disclosure relates to an image sensor. More particularly, the present disclosure relates to the image sensor with nano-light pillars.

### Description of Related Art

In the field of complementary metal oxide semiconductor (CMOS) image sensor (CIS), the arrangements and dimensions of components in the image sensor would affect the phase and the distribution of light. If the lights with different wavelengths are not properly modulated, the light energy may be distributed into undesired regions, thereby lowering the sensitivity in light sensing. Therefore, there is a need for an image sensor with more precise light guiding function to improve the image performance of the sensor.

### SUMMARY

According to some embodiments of the present disclosure, an image sensor includes two first color filters corresponding to a first wavelength band, a second color filter corresponding to a second wavelength band different from the first wavelength band, and a third color filter corresponding to a third wavelength band different from the first wavelength band and the second wavelength band. The first color filters, the second color filter, and the third color filter are arranged in a color filter array of two rows by two columns, and the first color filters are diagonally disposed in the color filter array. The image sensor also includes a plurality of nano-light pillars above the color filter array. The plurality of the nano-light pillars, in a plan view, include two first nano-light pillars within each of the first color filters, two second nano-light pillars on each of boundary lines between the first color filters and the second color filter, a third nano-light pillar on each of the boundary lines between the first color filters and the second color filter, four fourth nano-light pillars within the second color filter, and a fifth nano-light pillar within the third color filter. A dimension of the fourth nano-light pillars and a dimension of the fifth nano-light pillar are larger than dimensions of the first nano-light pillars, the second nano-light pillars, and the third nano-light pillar.

In some embodiments, the plurality of the nano-light pillars are spaced apart from boundary lines between the first color filters and the third color filter.

In some embodiments, the plurality of the nano-light pillars are spaced apart from corners of the first color filters, the second color filter, and the third color filter.

In some embodiments, a center of the fifth nano-light pillar is aligned with a center of the third color filter along a direction which is perpendicular to the plan view.

In some embodiments, one of the first color filters is divided into four regions by a first symmetry axis and a second symmetry axis in the plan view, and the first symmetry axis intersects centers of the first nano-light pillars within the one of the first color filters.

In some embodiments, extended lines extend through centers of each adjacent two of the four regions, and the extended lines intersect the centers of the first nano-light pillars within the one of the first color filters.

In some embodiments, extended lines extend through centers of each adjacent two of the four regions, and the centers of the first nano-light pillars within the one of the first color filters are offset from the extended lines.

In some embodiments, extended lines extend through centers of each adjacent two of the four regions, and the extended lines intersect centers of the second nano-light pillars on the boundary line between the one of the first color filters and the second color filter.

In some embodiments, the second symmetry axis intersects a center of the third nano-light pillar on the boundary line between the one of the first color filters and the second color filter.

In some embodiments, centers of the second nano-light pillars and the third nano-light pillar are offset from each of the boundary lines.

In some embodiments, the second color filter is divided into four regions by a first symmetry axis and a second symmetry axis in the plan view, and centers of the fourth nano-light pillars are aligned with centers of the four regions along a direction which is perpendicular to the plan view, respectively.

In some embodiments, the nano-light pillars, in the plan view, further include four sixth nano-light pillars within the second color filter. The sixth nano-light pillars and the fourth nano-light pillars are alternately arranged around a center of the second color filter, and a dimension of the sixth nano-light pillars is larger than the dimension of the fourth nano-light pillars.

In some embodiments, the second color filter is divided into four regions by a first symmetry axis and a second symmetry axis in the plan view, extended lines extend through centers of each adjacent two of the four regions, and centers of the fourth nano-light pillars and the sixth nano-light pillars are offset from the extended lines.

In some embodiments, the nano-light pillars, in the plan view, further include a seventh nano-light pillar within the second color filter, where a center of the seventh nano-light pillar is aligned with the center of the second color filter along a direction which is perpendicular to the plan view.

In some embodiments, the nano-light pillars, in the plan view, further include an eighth nano-light pillar on each of junction corners between the first color filters, the second color filter, and the third color filter.

In some embodiments, the nano-light pillars, in the plan view, further include four ninth nano-light pillars within each of the first color filters and around a center of each of the first color filters, four tenth nano-light pillars within the third color filter and around a center of the third color filter, and an eleventh nano-light pillar within each of the first color filters, where a center of the eleventh nano-light pillar is aligned with the center of each of the first color filters along the direction which is perpendicular to the plan view. The dimension of the fifth nano-light pillar is larger than a dimension of the eleventh nano-light pillar, and a dimension of the tenth nano-light pillars is larger than a dimension of the ninth nano-light pillars.

In some embodiments, the nano-light pillars, in the plan view, further include an eighth nano-light pillar on each of junction corners between the first color filters, the second color filter, and the third color filter.

In some embodiments, the nano-light pillars, in the plan view, further include an eighth nano-light pillar on each of junction corners between the first color filters, the second color filter, and the third color filter, four ninth nano-light pillars within each of the first color filters and around a center of each of the first color filters, and four tenth nano-light pillars within the third color filter and around a center of the third color filter. A dimension of the tenth nano-light pillars is larger than the dimension of the second nano-light pillars, a dimension of the eighth nano-light pillar, and a dimension of the ninth nano-light pillar.

In some embodiments, one of the nano-light pillars has a first dimension in a range of 60 nm to 200 nm, and another one of the nano-light pillars has a second dimension in a range of 200 nm to 600 nm.

In some embodiments, the first color filters are two green color filters or two clear color filters, the second color filter is a red color filter, and the third color filter is a blue color filter.

According to the embodiments of the present disclosure, the image sensor includes the nano-light pillars above the color filter array to provide hybrid function of the light scattering and the light phase controlling. The light with different wavelengths may be scattered into the specific positions by the nano-light pillars arranged in the suitable pattern, which manipulates the light energy received by the image sensor and improves the image performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a cross-sectional view of an image sensor according to one embodiment of the present disclosure.

FIG. 1B and FIG. 1C illustrate schematic plan views of the image sensor in FIG. 1A.

FIG. 1D illustrates a schematic plan view of an image sensor according to another embodiment of the present disclosure.

FIG. 2A illustrates a schematic plan view of an image sensor according to another embodiment of the present disclosure.

FIG. 2B illustrates a cross-sectional view of an image sensor according to another embodiment of the present disclosure.

FIG. 3 illustrates a quantum efficiency diagram of the image sensors according to some embodiments of the present disclosure.

FIGS. 4A, 4B, 5A, 5B, 6A, 6B, 7A, 7B, 8 and 9 illustrate schematic plan views of image sensors according to some embodiments of the present disclosure.

### DETAILED DESCRIPTION

The following disclosure provides many different embodiments, or examples, for implementing different features of the provided subject matter. Specific examples of components, arrangements, etc., are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that although the terms “first”, “second”, “third”, etc., can be used to describe various elements, components, regions, layers and/or parts in this specification, these elements, components, regions, layers and/or parts should not be limited by these terms. These terms are used only to distinguish one element, component, region, layer, or part from another element, component, region, layer, or part. Therefore, the first element, component, region, layer, or part discussed below may be referred to as a second element, component, region, layer, or part without departing from the instructions of the specification.

The present disclosure provides an image sensor including multiple nano-light pillars above the color filter array to provide hybrid function of the light scattering and the light phase controlling. After the light transmits through the nano-light pillars arranged in the suitable pattern, the light with different wavelengths may be scattered into the specific position to manipulate the light energy received by the photodiodes below the color filters. Therefore, the precision and the sensitivity of the image sensor can be increased to improve the image performance.

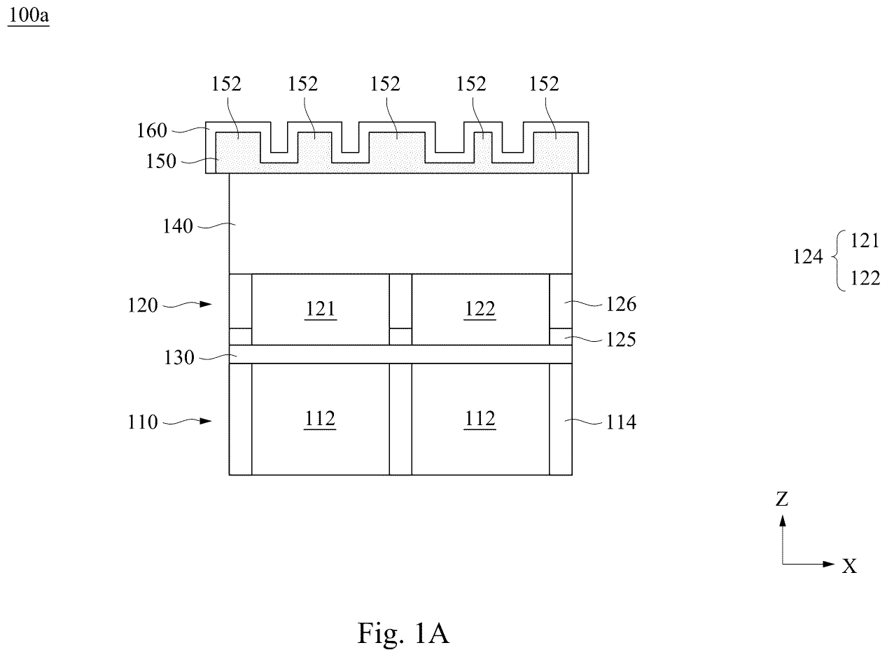

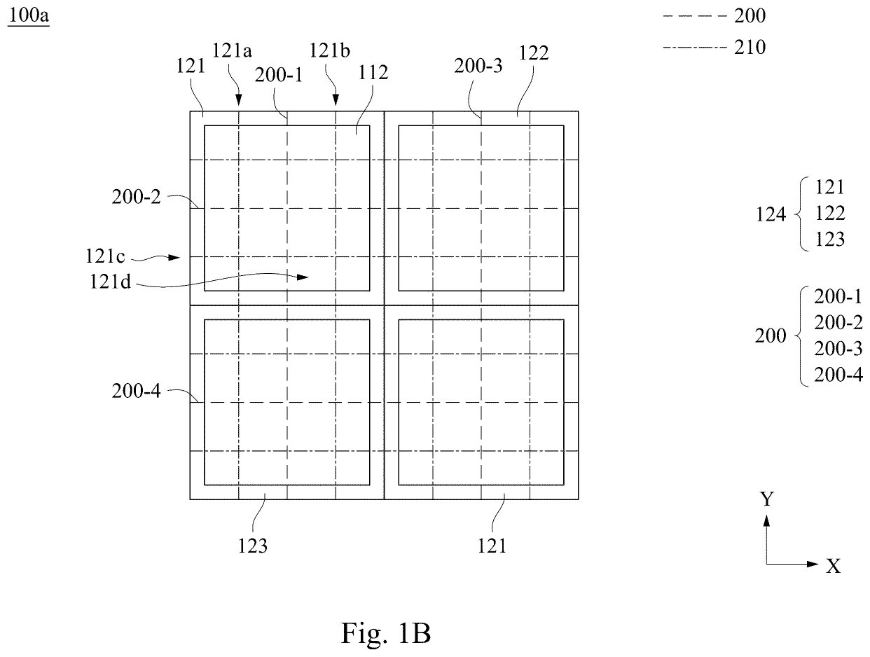

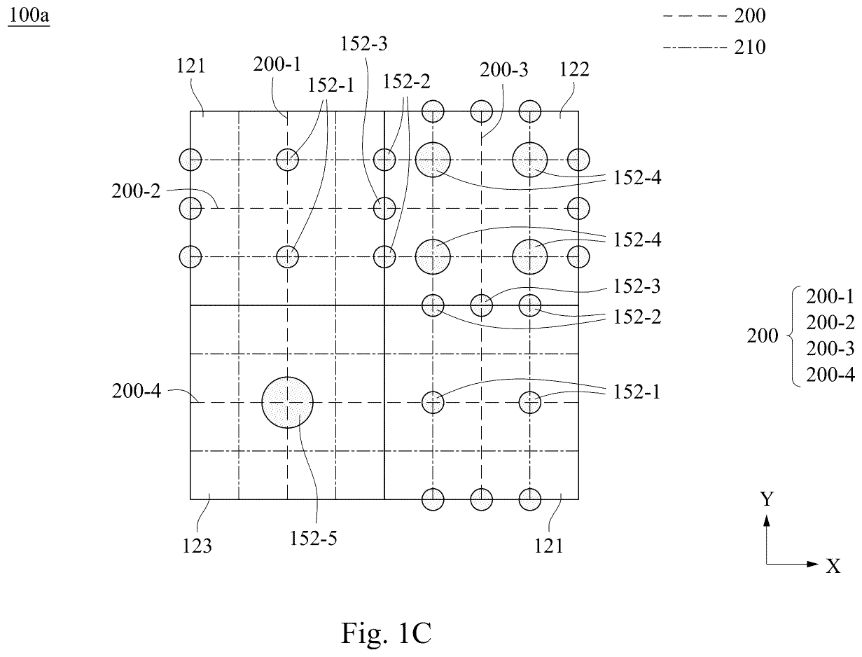

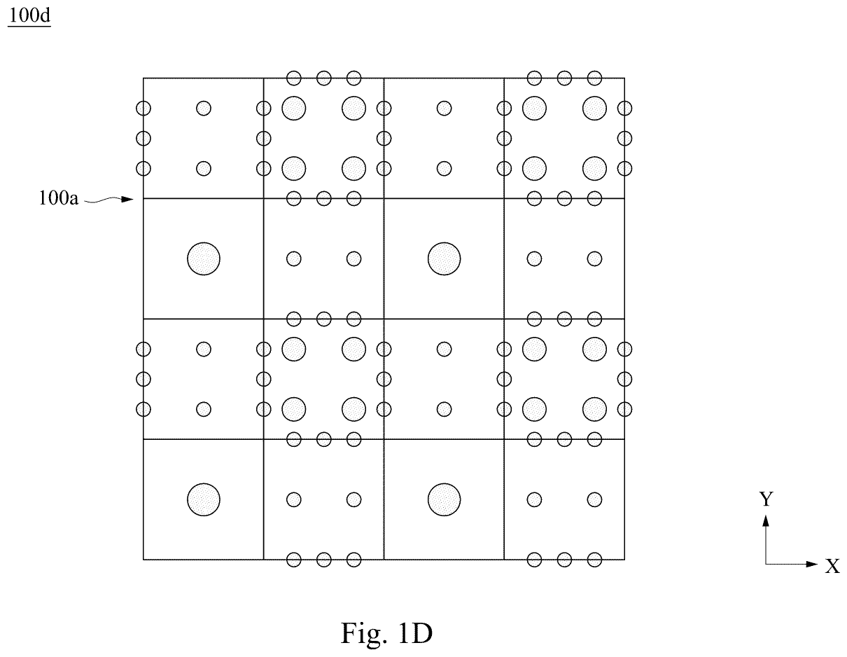

According to one embodiment of the present disclosure, FIG. 1A illustrates a cross-sectional view of an image sensor 100a in the X-Z plane. FIG. 1B and FIG. 1C illustrate schematic plan views of the image sensor 100a in FIG. 1A in the X-Y plane to discuss the component arrangement in the image sensor 100a, where some components are omitted in FIG. 1B and FIG. 1C for clarity. The image sensor 100a includes a photoelectric conversion layer 110, a color filter layer 120 above the photoelectric conversion layer 110, an anti-reflection layer 130 between the photoelectric conversion layer 110 and the color filter layer 120, an underlying layer 140 on the color filter layer 120, and a nano-light pillar layer 150 on the underlying layer 140. The nano-light pillar layer 150 includes a plurality of nano-light pillars 152 for the light scattering and the light phase controlling, which improves the image performance of the image sensor 100a.

Specifically, the photoelectric conversion layer 110 includes a plurality of photodiodes 112 and a plurality of deep trench isolations (DTIs) 114. The DTIs 114 separate each of the photodiodes 112. The color filter layer 120 includes a plurality of color filters, such as a first color filter 121 corresponding to a first wavelength band, a second color filter 122 corresponding to a second wavelength band different from the first wavelength band, and a third color filter 123 corresponding to a third wavelength band different from the first wavelength band and the second wavelength band. The color filters 121-123 are separated by isolation grids 126 including a metal grid 125, where a material of the metal grid 125 may include an absorbent metal, such as W, TiN, Cu, or Al.

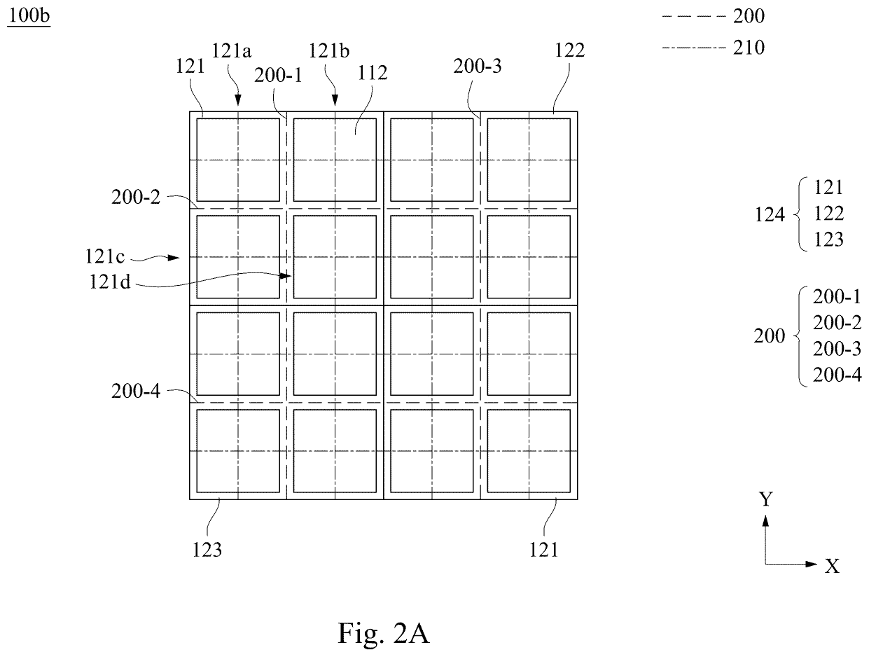

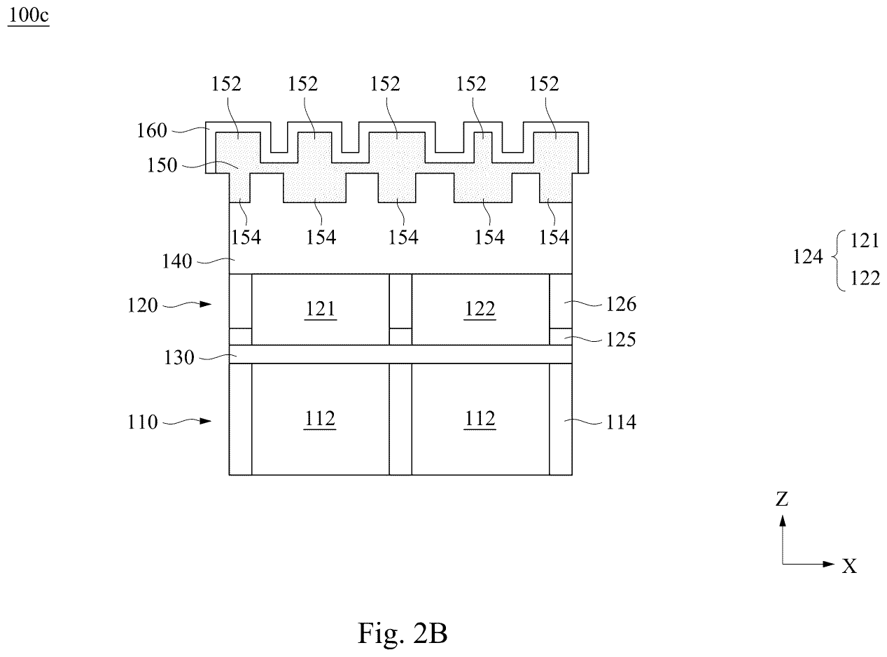

In some embodiments, as shown in FIG. 1B, one color filter of the color filter layer 120 may correspond to one photodiode 112. In some other embodiments, one color filter of the color filter layer 120 may correspond to more than one photodiode 112. FIG. 2A illustrates a schematic plan view of an image sensor 100b in the X-Y plane according to one alternative embodiment of the present disclosure. The image sensor 100b is similar to the image sensor 100a, except that one color filter of the color filter layer 120 corresponds to four photodiodes 112.

Referring back to FIGS. 1A-1C, the color filters 121-123 of the color filter layer 120 are arranged in a color filter array 124 of two rows by two columns. Specifically, the color filter array 124 includes two first color filters 121, one second color filter 122, and one third color filter 123, where the two first color filters are diagonally disposed in the color filter array 124. In some embodiments, each of the color filters 121-123 may be a green, red, blue, clear, yellow, cyan, or magenta color filter. In some preferred embodiments, the two first color filters 121 may be two green color filters or two clear color filters, the second color filter 122 may be a red color filter, and the third color filter 123 may be a blue color filter.

Each of the color filters 121-123 of the color filter layer 120 may be divided into four regions by two symmetry axes 200. For example, as shown in FIG. 1B, the first color filter 121 at the top-left position in the color filter array 124 is divided into four regions 121a-121d by a symmetry axis 200-1 and a symmetry axis 200-2, where the symmetry axis 200-1 and the symmetry axis 200-2 are parallel to the boundary lines of the first color filter 121. Extended lines 210 are parallel to the boundary lines of the first color filter 121 and extend through the centers of each adjacent two of the four regions 121a-121d, which divides each of the four regions 121a-121d into four smaller regions. It should be noted that the symmetry axes 200 and the extended lines 210 are marked lines for arranging the components, and the first color filter 121 is not actually cut or sliced by the symmetry axes 200 and the extended lines 210.

Similarly, the second color filter 122 is divided into four regions by the symmetry axis 200-2 and a symmetry axis 200-3, where the symmetry axis 200-2 and the symmetry axis 200-3 are parallel to the boundary lines of the second color filter 122. The third color filter 123 is divided into four regions by the symmetry axis 200-1 and a symmetry axis 200-4, where the symmetry axis 200-1 and the symmetry axis 200-4 are parallel to the boundary lines of the third color filter 123. The first color filter 121 at the bottom-right position in the color filter array 124 is divided into four regions by the symmetry axis 200-3 and the symmetry axis 200-4. The extended lines 210 are parallel to the boundary lines of the color filters 121-123 and extend through the centers of each adjacent two of the four regions of each of the color filters 121-123. The division of the color filters 121-123 illustrated in FIG. 1B is related to the arrangement of the nano-light pillars 152, which will be further discussed below.

The nano-light pillar layer 150 covers the top surface of the underlying layer 140 such that a projection of the nano-light pillar layer 150 onto the anti-reflection layer 130 fully overlaps a projection of the color filter array 124 onto the anti-reflection layer 130. The plurality of nano-light pillars 152 of the nano-light pillar layer 150 protrude from the top surface of the nano-light pillar layer 150 and away from the color filter array 124 in the Z-axis direction. The nano-light pillars 152 are spaced apart from each other so that the nano-light pillars 152 are able to scatter the light into neighboring color filters 121-123.

The nano-light pillars 152 above the color filters 121-123 may have different dimensions and arrangements depend on the respective wavelength band of each of the color filters 121-123. When the nano-light pillars 152 are arranged in a specific pattern corresponding to the color filters 121-123 of the color filter array 124, the nano-light pillars 152 could simultaneously scatter the light and modulate the light phase reaching the color filter array 124, instead of scattering alone or controlling the phase alone. The light modulation by the nano-light pillars 152 manipulates the light energy received by the photodiodes 112 below the color filters 121-123 having different wavelength bands, which improves the image performance of the image sensor 100a.

For example, in the embodiments which the color filter array 124 includes the four color filters 121-123 illustrated in FIG. 1C, the nano-light pillars 152 include two first nano-light pillars 152-1 within each of the first color filters 121, two second nano-light pillars 152-2 on each of boundary lines between the first color filters 121 and the second color filter 122, a third nano-light pillar 152-3 on each of the boundary lines between the first color filters 121 and the second color filter 122, four fourth nano-light pillars 152-4 within the second color filter 122, and a fifth nano-light pillar 152-5 within the third color filter 123.

As shown in FIG. 1C, the first nano-light pillars 152-1 within the first color filter 121 at the top-left position of the color filter array 124 are spaced apart from the boundary lines of the first color filter 121, and the symmetry axis 200-1 intersects the centers of the first nano-light pillars 152-1. Similarly, the first nano-light pillars 152-1 within the first color filter 121 at the bottom-right position of the color filter array 124 are spaced apart from the boundary lines of the first color filter 121, and the symmetry axis 200-3 intersects the centers of the first nano-light pillars 152-1. In some embodiments, the extended lines 210 may also intersect the centers of the first nano-light pillars 152-1, where the extended lines 210 extend through the centers of each adjacent two of the four regions of the first color filter 121.

The extended lines 210 intersect the centers of the second nano-light pillars 152-2 on the boundary line between the first color filter 121 and the second color filter 122, where the extended lines 210 extend through the centers of each adjacent two of the four regions of the first color filter 121. The symmetry axis 200-2 intersects the center of the third nano-light pillar 152-3 on the boundary line between the first color filter 121 and the second color filter 122. In some embodiments, the boundary line between the first color filter 121 and the second color filter 122 may also intersect the centers of the second nano-light pillars 152-2 and the third nano-light pillar 152-3.

The fourth nano-light pillars 152-4 are spaced apart from the boundary lines of the second color filter 122 and arranged around the center of the second color filter 122. The extended lines 210 may intersect the centers of the fourth nano-light pillars 152-4, where the extended lines 210 extend through the centers of each adjacent two of the four regions of the second color filter 122. In some embodiments, the centers of the four fourth nano-light pillars 152-4 may be aligned with the centers of the four regions of the second color filter 122 along the Z-axis direction, respectively. The center of the fifth nano-light pillar 152-5 is aligned with the center of the third color filter 123 along the Z-axis direction. The nano-light pillars 152-1 to 152-5 may be spaced apart from the boundary lines between the first color filters 121 and the third color filter 123, and the nano-light pillars 152-1 to 152-5 may be spaced apart from corners of the first color filters 121, the second color filter 122, and the third color filter 123.

In addition to the position arrangement, the dimensions of the nano-light pillars 152 are also adjusted to optimize the hybrid function of the light scattering and phase controlling of the nano-light pillars 152. Specifically, the dimension of the fourth nano-light pillars 152-4 and the dimension of the fifth nano-light pillar 152-5 are larger than dimensions of the first nano-light pillars 152-1, the second nano-light pillars 152-2, and the third nano-light pillar 152-3. The dimension of the fifth nano-light pillars 152-5 may be larger than, equal to, or smaller than the dimension of the fourth nano-light pillars 152-4. The dimension of the third nano-light pillar 152-3 may be larger than, equal to, or smaller than the dimensions of the second nano-light pillars 152-2 and the first nano-light pillars 152-1. In the embodiments which the nano-light pillars 152 are right cylinders having circle cross-sections, the dimension of one nano-light pillar indicates the radius of the circle cross-section of the nano-light pillar.

In some embodiments, some of the nano-light pillars 152 may have a first dimension in a range of 60 nm to 200 nm, and some other nano-light pillars 152 may have a second dimension in a range of 200 nm to 600 nm. For example, the dimensions of the first nano-light pillars 152-1, the second nano-light pillars 152-2, and the third nano-light pillar 152-3 in FIG. 1C may be in the range of 60 nm to 200 nm, such as 100 nm, 140 nm, or 180 nm, while the dimensions of the fourth nano-light pillars 152-4 and the fifth nano-light pillars 152-5 may be in the range of 200 nm to 600 nm, such as 300 nm, 400 nm, or 500 nm.

In some embodiments, a refractive index of the nano-light pillar layer 150 may be larger than a refractive index of the underlying layer 140 to scatter the incident light into the specific positions of the image sensor 100a. Since the refractive indexes of the nano-light pillars 152 of the nano-light pillar layer 150 and the underlying layer 140 are different, it could provide sufficient interfaces with different refractive indexes to modulate the light phase. For example, the refractive index of the nano-light pillar layer 150 may be in a range from 1.4 to 2.6, such as 1.8, 2, 2.2, or 2.4, while the refractive index of the underlying layer 140 may be in a range from 1.2 to 1.8, such as, 1.3, 1.4, 1.5, 1.6, or 1.7.

In some embodiments, the nano-light pillar layer 150 may further include a plurality of nano-light pillars 154 protrude from the bottom surface of the nano-light pillar layer 150 and toward the color filter array 124 in the Z-axis direction to enhance the light scattering and phase controlling of the nano-light pillars 152. FIG. 2B illustrates a cross-sectional view of an image sensor 100c in the X-Z plane according to one alternative embodiment of the present disclosure. The image sensor 100c is similar to the image sensor 100a in FIGS. 1A-1C, except that the image sensor 100c includes the nano-light pillars 154 protruding from the nano-light pillar layer 150. The centers of the nano-light pillars 154 may be aligned with the centers of the nano-light pillars 152 along the Z-axis direction, respectively, such that each of the nano-light pillars 154 corresponds to one of the nano-light pillars 152. The dimension of each of the nano-light pillars 154 may be larger than, equal to, or smaller than that of the corresponding nano-light pillar 152.

In some embodiments, referring back to FIGS. 1A-1C, the image sensor 100a may further include a capping layer 160 conformally and continuously covering the top surface and the sidewalls of the nano-light pillar layer 150. As a result, the top surface and the sidewalls of the nano-light pillars 152 are covered and protected by the capping layer 160. A refractive index of the capping layer 160 may be different from the refractive index of the nano-light pillar layer 150. The refractive index of the capping layer 160 may be in a range from 1.4 to 1.6, such as 1.45, 1.5, or 1.55.

In some embodiments, the image sensor 100a in FIGS. 1A-1C may be a repeating unit for the final image sensor device. As an exemplary embodiment, FIG. 1D illustrates a schematic plan view of an image sensor 100d in the X-Y plane, where the image sensor 100d includes four image sensors 100a. Referring to FIGS. 1C-1D, the image sensors 100a are assembled together by splicing the boundary lines of the color filter array 124, while either two adjacent color filters have different wavelength bands. The nano-light pillars 152 on the boundary lines of the color filter array 124 may be shared by the adjacent color filter arrays 124.

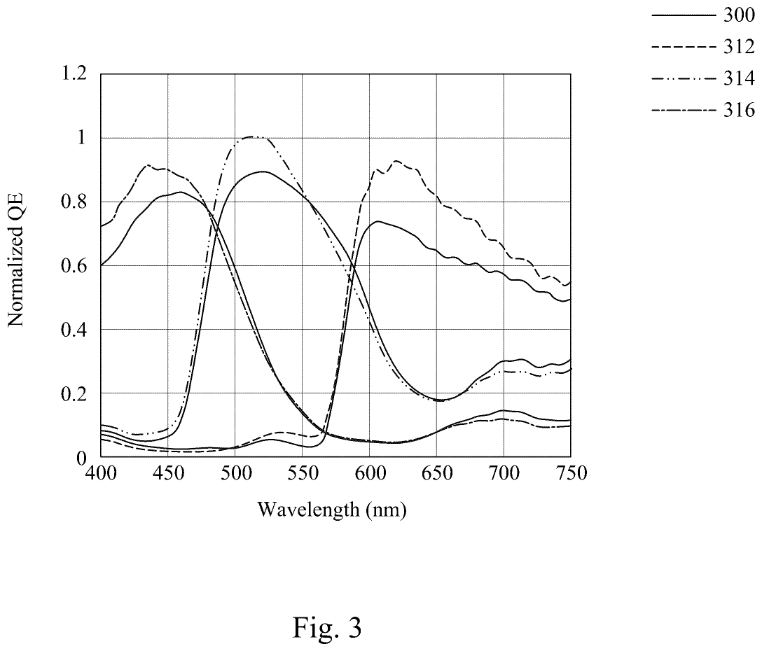

As mentioned above, the nano-light pillars 152 scatter the light and control the light phase so that the photodiodes 112 receive more light energy corresponding to the wavelength bands of the color filters 121-123. FIG. 3 illustrates the quantum efficiency (QE) diagram of the image sensors in a visible light wavelength range according to some embodiments of the present disclosure. The spectrums 312-316 in FIG. 3 were obtained from the image sensor 100a in FIGS. 1A-1C, in which the spectrums 312-316 represent the blue light, the green light, and the red light, respectively. The spectrum 300 was obtained from a comparative image sensor similar to the image sensor 100a but without the nano-light pillar layer 150, in which the spectrum 300 shows three peaks representing the blue light, the green light, and the red light. As shown in FIG. 3, the quantum efficiencies of the spectrums 312-316 are higher than those of the three peaks of the spectrum 300, which indicates the image sensor 100a including the nano-light pillar layer 150 receives higher light energy.

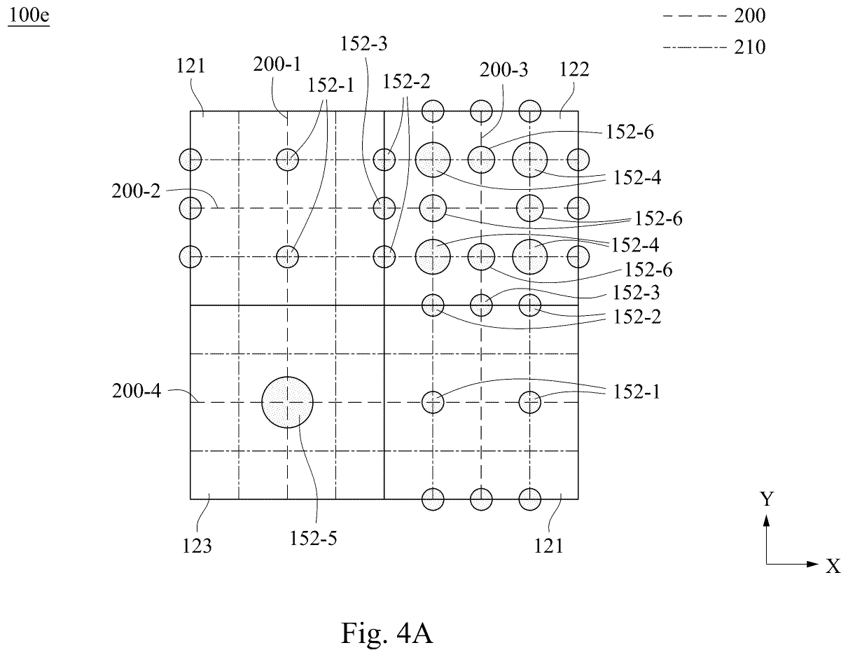

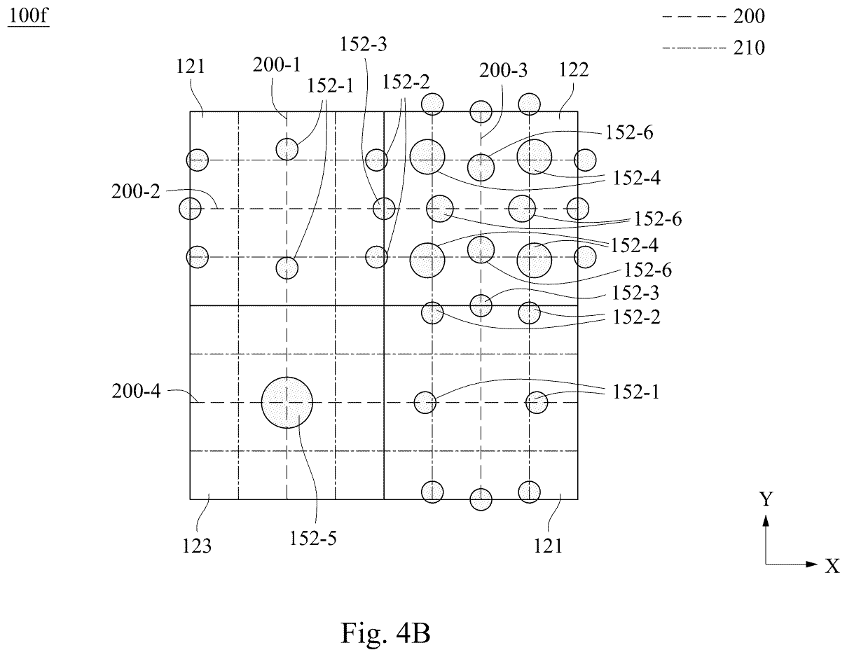

According to one alternative embodiment of the present disclosure, FIG. 4A illustrates a schematic plan view of an image sensor 100e in the X-Y plane. The image sensor 100e is similar to the image sensor 100a in FIGS. 1A-1C, except for the arrangement of the nano-light pillars 152. Compared to the image sensor 100a, the image sensor 100e further includes four sixth nano-light pillars 152-6 within the second color filter 122. The sixth nano-light pillars 152-6 are spaced apart from the boundary lines of the second color filter 122, and the four sixth nano-light pillars 152-6 and the four fourth nano-light pillars 152-4 are alternately arranged around the center of the second color filter 122.

As the second color filter 122 is divided into four regions by the symmetry axis 200-2 and the symmetry axis 200-3 in the plan view, the extended lines 210 may intersect the centers of the sixth nano-light pillars 152-6, where the extended lines 210 extend through the centers of each adjacent two of the four regions of the second color filter 122. In some embodiments, the centers of the sixth nano-light pillars 152-6 may be aligned with the centers of the fourth nano-light pillars 152-4 along the X-axis direction.

When the sixth nano-light pillars 152-6 exist in the image sensor 100e, the dimension of the sixth nano-light pillars 152-6 is larger than the dimension of the fourth nano-light pillars 152-4 and correspondingly larger than the dimensions of the of the first nano-light pillars 152-1, the second nano-light pillars 152-2, and the third nano-light pillars 152-3. The dimension of the sixth nano-light pillars 152-6 may be larger than, equal to, or smaller than the dimension of the fifth nano-light pillar 152-5.

According to one alternative embodiment of the present disclosure, FIG. 4B illustrates a schematic plan view of an image sensor 100f in the X-Y plane. The image sensor 100f is similar to the image sensor 100e in FIG. 4A, except for the arrangement of the nano-light pillars 152. Compared to the image sensor 100e, some positions of the centers of the nano-light pillars 152 in the image sensor 100f are offset such that the boundary lines, the symmetry axes 200, or the extended line 210 of the color filters 121-123 may not intersect the centers of the nano-light pillars 152. When the center of the nano-light pillar 152 is referred to as “offset” herein, the center of the nano-light pillars 152 may be offset inwardly to become closer to the closest center of the color filters 121-123, or the centers of the nano-light pillars 152 may be offset outwardly to become further from the closest center of the color filters 121-123.

Specifically, as each of the color filters 121-123 is divided into four regions by the symmetry axes 200 in the plan view, the centers of the first nano-light pillars 152-1 within both of the first color filters 121 are offset from the extended lines 210, where the extended lines 210 extend through the centers of each adjacent two of the four regions of the corresponding first color filter 121. The centers of the second nano-light pillars 152-2 and the third nano-light pillar 152-3 on each of the boundary lines are offset from the corresponding boundary line, where the centers of the second nano-light pillars 152-2 and the third nano-light pillar 152-3 may be offset in opposite directions. The centers of the fourth nano-light pillars 152-4 and the sixth nano-light pillars 152-6 are offset from the extended lines 210, where the extended lines 210 extend through the centers of each adjacent two of the four regions of the second color filter 122. The centers of the fourth nano-light pillars 152-4 and the sixth nano-light pillars 152-6 may be offset in opposite directions. Taking FIG. 4B as an example, the centers of the first nano-light pillars 152-1, the second nano-light pillars 152-2, and the fourth nano-light pillars 152-4 are offset outwardly to become further from the center of the second color filter 122, while the centers of the third nano-light pillar 152-3 and the sixth nano-light pillars 152-6 are offset inwardly to become closer to the center of the second color filter 122.

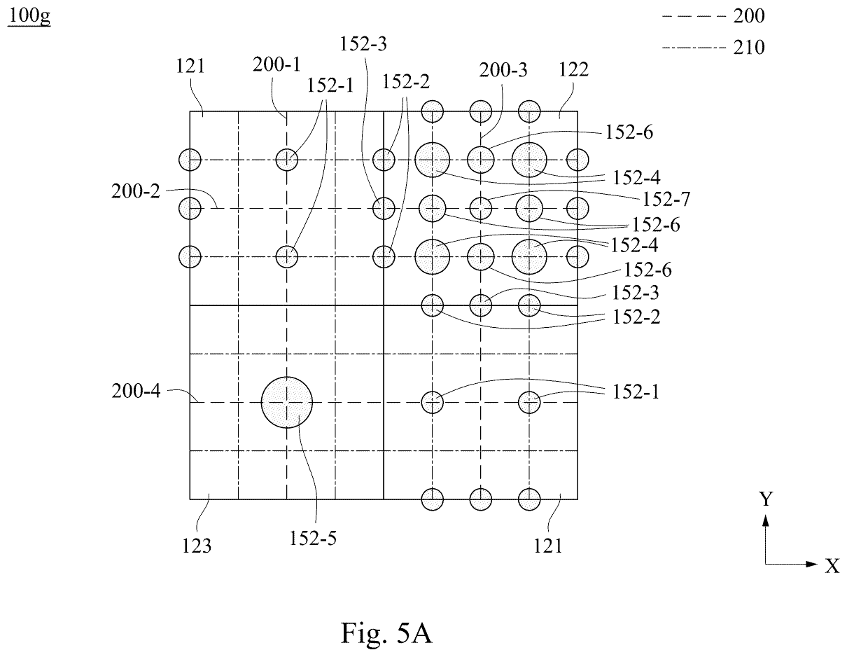

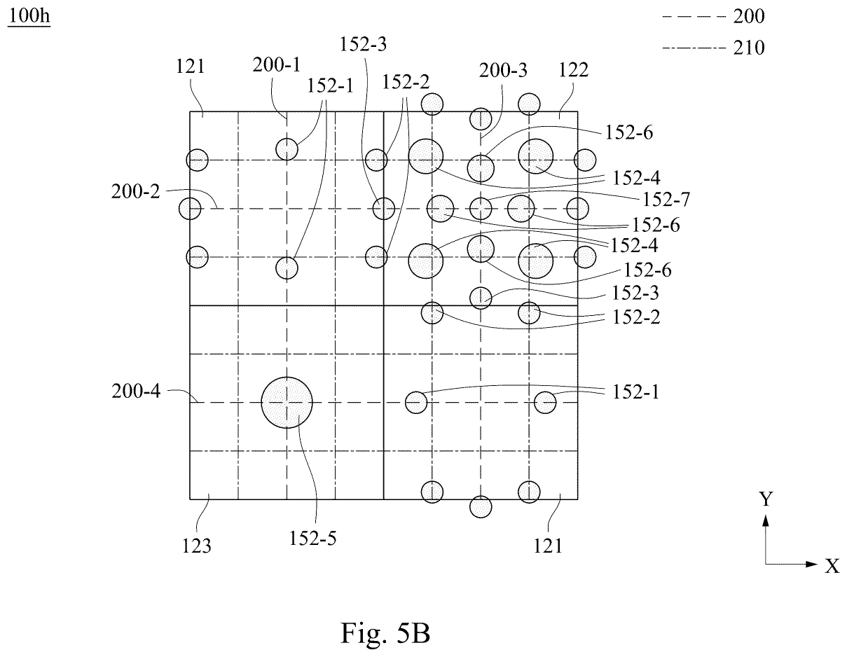

According to one alternative embodiment of the present disclosure, FIG. 5A illustrates a schematic plan view of an image sensor 100g in the X-Y plane. The image sensor 100g is similar to the image sensor 100e in FIG. 4A, except for the arrangement of the nano-light pillars 152. Compared to the image sensor 100e, the image sensor 100g further includes a seventh nano-light pillar 152-7 within the second color filter 122. The center of the seventh nano-light pillar 152-7 is aligned with the center of the second color filter 122 along the Z-axis direction such that the four sixth nano-light pillars 152-6 and the four fourth nano-light pillars 152-4 are alternately arranged around and spaced apart from the seventh nano-light pillar 152-7. The dimension of the seventh nano-light pillar 152-7 may be larger than, equal to, or smaller than the dimension of the sixth nano-light pillars 152-6.

According to one alternative embodiment of the present disclosure, FIG. 5B illustrates a schematic plan view of an image sensor 100h in the X-Y plane. The image sensor 100h is similar to the image sensor 100g in FIG. 5A, except for the arrangement of the nano-light pillars 152. Compared to the image sensor 100g, some positions of the centers of the nano-light pillars 152 in the image sensor 100h are offset such that the boundary lines, the symmetry axes 200, or the extended line 210 of the first color filter 121 to third color filter 123 may not intersect the centers of the nano-light pillars 152.

Specifically, as each of the color filters 121-123 is divided into four regions by the symmetry axes 200 in the plan view, the centers of the first nano-light pillars 152-1 within both of the first color filters 121 are offset from the extended lines 210, where the extended lines 210 extend through the centers of each adjacent two of the four regions of the corresponding first color filter 121. The centers of the second nano-light pillars 152-2 and the third nano-light pillar 152-3 on each of the boundary lines are offset from the corresponding boundary line, where the centers of the second nano-light pillars 152-2 and the third nano-light pillar 152-3 may be offset in opposite directions. The centers of the fourth nano-light pillars 152-4 and the sixth nano-light pillars 152-6 are offset from the extended lines 210, where the extended lines 210 extend through the centers of each adjacent two of the four regions of the second color filter 122. The centers of the fourth nano-light pillars 152-4 and the sixth nano-light pillars 152-6 may be offset in opposite directions.

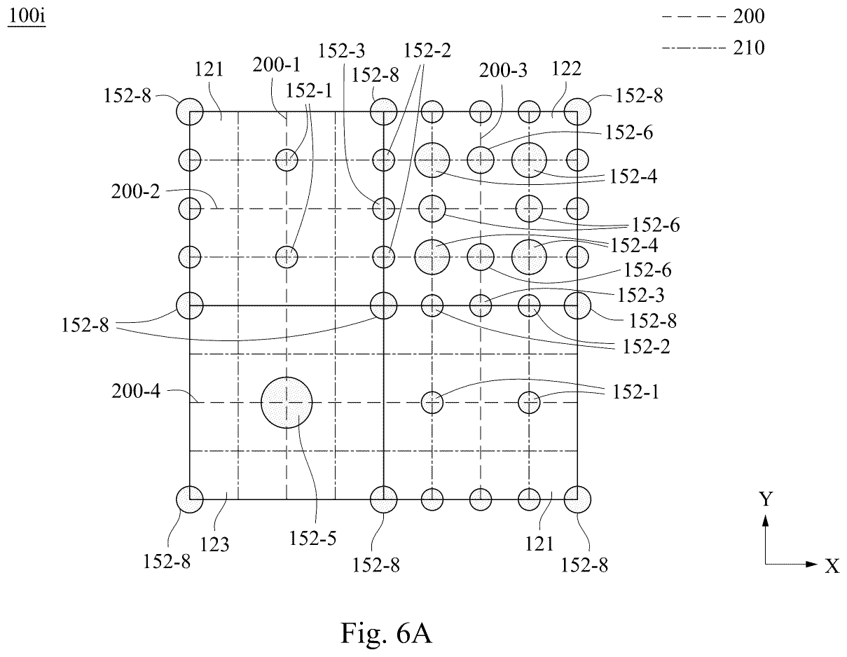

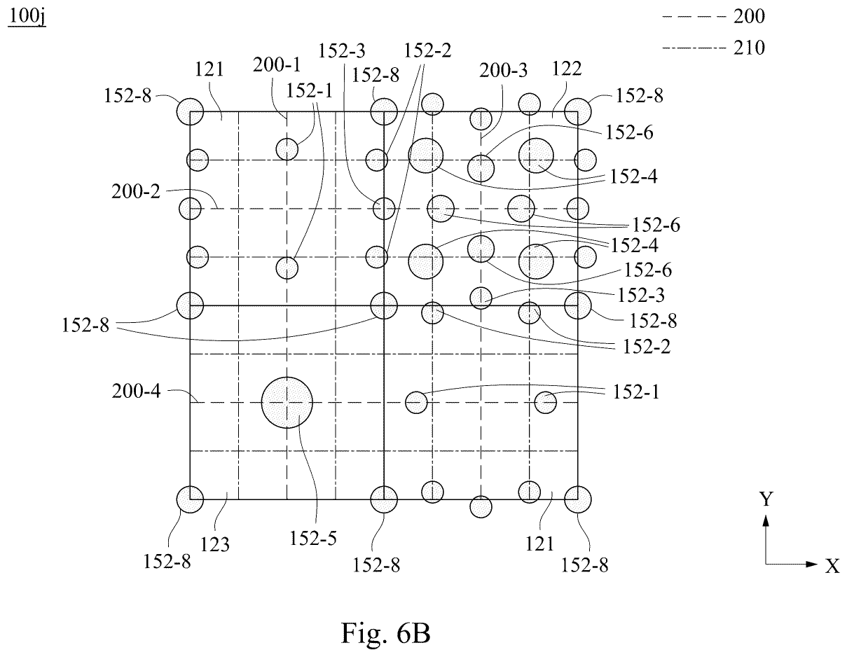

According to one alternative embodiment of the present disclosure, FIG. 6A illustrates a schematic plan view of an image sensor 100i in the X-Y plane. The image sensor 100i is similar to the image sensor 100e in FIG. 4A, except for the arrangement of the nano-light pillars 152. Compared to the image sensor 100e, the image sensor 100i further includes an eighth nano-light pillar 152-8 on each of the junction corners between the first color filters 121, the second color filter 122, and the third color filter 123. In other words, the image sensor 100e includes nine eighth nano-light pillars 152-8 in one color filter array 124. In some embodiments, the boundary lines of the color filters 121-123 form multiple intersection points, where centers of the eighth nano-light pillars 152-8 may be aligned with the intersection points along the Z-axis direction, respectively. The dimension of the eighth nano-light pillars 152-8 may be larger than, equal to, or smaller than the dimension of the sixth nano-light pillars 152-6.

According to one alternative embodiment of the present disclosure, FIG. 6B illustrates a schematic plan view of an image sensor 100j in the X-Y plane. The image sensor 100j is similar to the image sensor 100i in FIG. 6A, except for the arrangement of the nano-light pillars 152. Compared to the image sensor 100i, some positions of the centers of the nano-light pillars 152 in the image sensor 100j are offset such that the boundary lines, the symmetry axes 200, or the extended line 210 of the first color filter 121 to third color filter 123 may not intersect the centers of the nano-light pillars 152.

Specifically, as each of the color filters 121-123 is divided into four regions by the symmetry axes 200 in the plan view, the centers of the first nano-light pillars 152-1 within both of the first color filters 121 are offset from the extended lines 210, where the extended lines 210 extend through the centers of each adjacent two of the four regions of the corresponding first color filter 121. The centers of the second nano-light pillars 152-2 and the third nano-light pillar 152-3 on each of the boundary lines are offset from the corresponding boundary line, where the centers of the second nano-light pillars 152-2 and the third nano-light pillar 152-3 may be offset in opposite directions. The centers of the fourth nano-light pillars 152-4 and the sixth nano-light pillars 152-6 are offset from the extended lines 210, where the extended lines 210 extend through the centers of each adjacent two of the four regions of the second color filter 122. The centers of the fourth nano-light pillars 152-4 and the sixth nano-light pillars 152-6 may be offset in opposite directions.

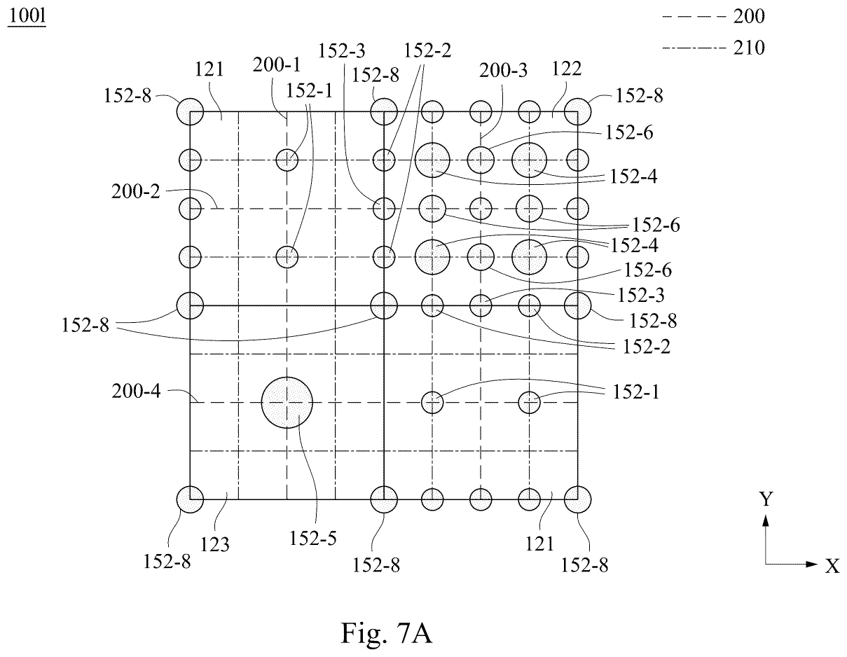

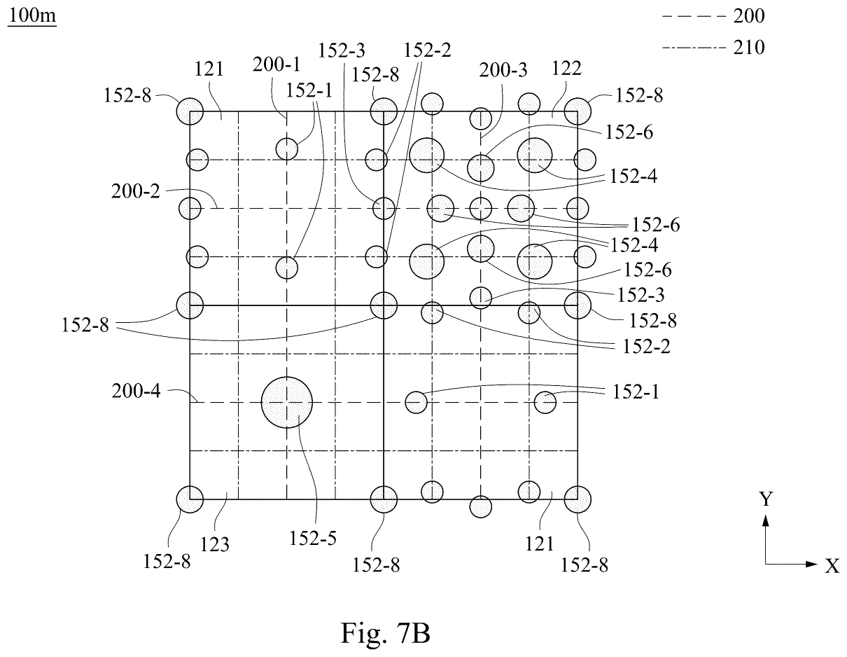

According to one alternative embodiment of the present disclosure, FIG. 7A illustrates a schematic plan view of an image sensor 100l in the X-Y plane. The image sensor 100l is similar to the image sensor 100g in FIG. 5A, except for the arrangement of the nano-light pillars 152. Compared to the image sensor 100g, the image sensor 100l further includes an eighth nano-light pillar 152-8 on each of the junction corners between the first color filters 121, the second color filter 122, and the third color filter 123. In other words, the image sensor 100l includes nine eighth nano-light pillars 152-8 in one color filter array 124. The boundary lines of the color filters 121-123 form multiple intersection points, where the centers of the eighth nano-light pillars 152-8 are aligned with the corresponding intersection points along the Z-axis direction, respectively. The dimension of the eighth nano-light pillars 152-8 may be larger than, equal to, or smaller than the dimension of the sixth nano-light pillars 152-6.

According to one alternative embodiment of the present disclosure, FIG. 7B illustrates a schematic plan view of an image sensor 100m in the X-Y plane. The image sensor 100m is similar to the image sensor 100l in FIG. 7A, except for the arrangement of the nano-light pillars 152. Compared to the image sensor 100l, some positions of the centers of the nano-light pillars 152 in the image sensor 100m are offset such that the boundary lines, the symmetry axes 200, or the extended line 210 of the first color filter 121 to third color filter 123 may not intersect the centers of the nano-light pillars 152. The offset of the nano-light pillars 152 in the image sensor 100m may be similar to that of the nano-light pillars 152 in the image sensor 100h and the image sensor 100j.

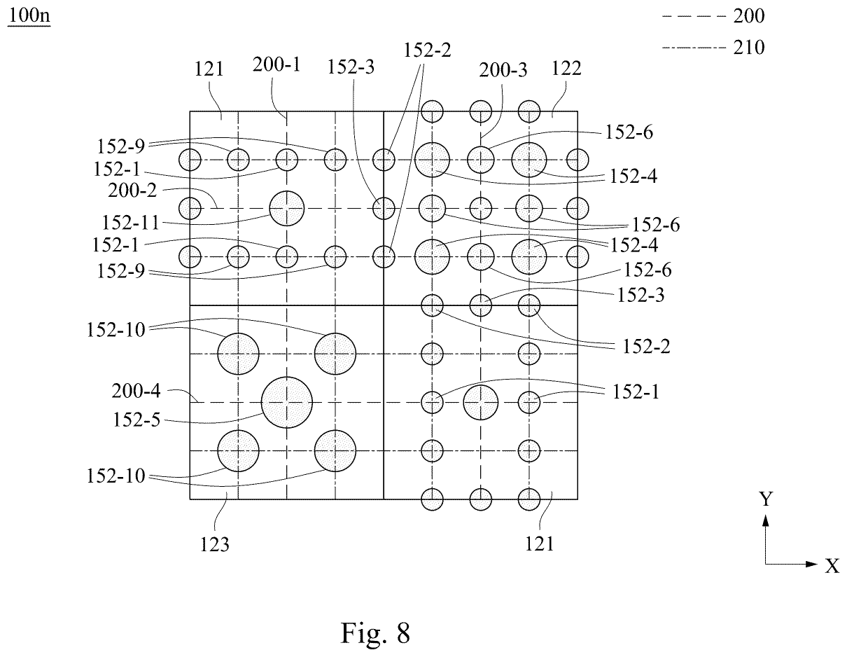

According to one alternative embodiment of the present disclosure, FIG. 8 illustrates a schematic plan view of an image sensor 100n in the X-Y plane. The image sensor 100n is similar to the image sensor 100g in FIG. 5A, except for the arrangement of the nano-light pillars 152. Compared to the image sensor 100g, the image sensor 100n further includes four ninth nano-light pillars 152-9 within each of the first color filters 121, four tenth nano-light pillars 152-10 within the third color filter 123, and an eleventh nano-light pillar 152-11 within each of the first color filter 121. The center of the eleventh nano-light pillar 152-11 is aligned with the center of the first color filter 121 along the Z-axis direction. The ninth nano-light pillars 152-9 are spaced apart from the boundary lines and around the center of the corresponding first color filter 121 such that the ninth nano-light pillars 152-9 and the first nano-light pillars 152-1 together surround the eleventh nano-light pillar 152-11. The tenth nano-light pillars 152-10 are spaced apart from the boundary lines and around the center of the third color filter 123 such that the tenth nano-light pillars 152-10 surround the fifth nano-light pillar 152-5.

In some embodiments, as the color filters 121-123 are respectively divided into four regions by the symmetry axes 200 in the plan view, the centers of the four ninth nano-light pillars 152-9 within each of the first color filters 121 may be aligned with the centers of the four regions of the corresponding first color filter 121 along the Z-axis direction, respectively. Similarly, the centers of the four tenth nano-light pillars 152-10 may be aligned with the centers of the four regions of the third color filter 123 along the Z-axis direction, respectively.

When the ninth nano-light pillars 152-9, the tenth nano-light pillars 152-10, and the eleventh nano-light pillar 152-11 exist in the image sensor 100n, the dimension of the fifth nano-light pillars 152-5 is larger than the dimension of the eleventh nano-light pillar 152-11, and the dimension of the tenth nano-light pillars 152-10 is larger than the dimension of the ninth nano-light pillars 152-9. The dimension of the tenth nano-light pillar 152-10 may be larger than, equal to, or smaller than the dimension of the fifth nano-light pillars 152-5. The dimension of the eleventh nano-light pillar 152-11 may be larger than, equal to, or smaller than the dimension of the ninth nano-light pillars 152-9.

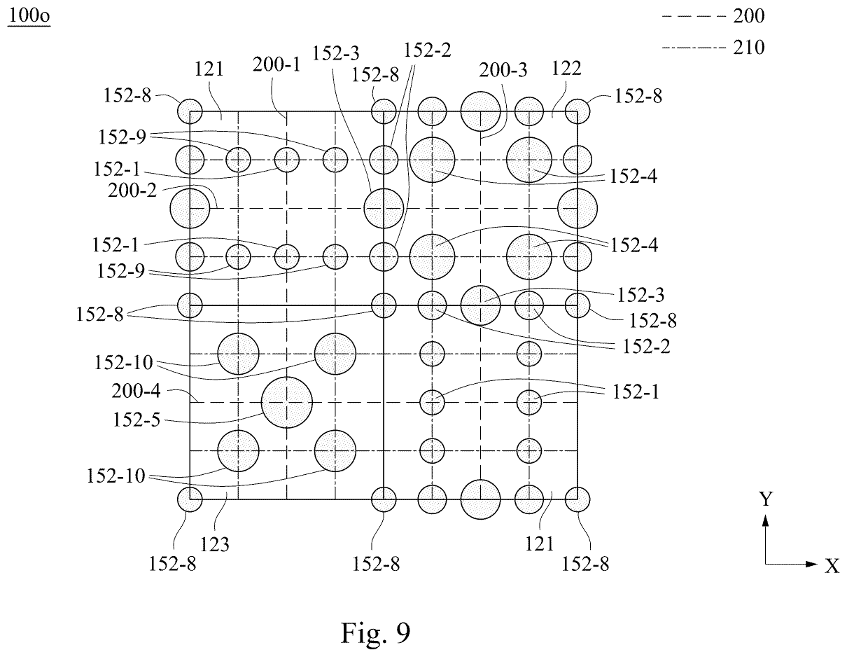

According to one alternative embodiment of the present disclosure, FIG. 9 illustrates a schematic plan view of an image sensor 100o in the X-Y plane. The image sensor 100o is similar to the image sensor 100i in FIG. 6A, except for the arrangement of the nano-light pillars 152. Compared to the image sensor 100i, the image sensor 100o further includes four ninth nano-light pillars 152-9 within each of the first color filters 121 and four tenth nano-light pillars 152-10 within the third color filter 123. The ninth nano-light pillars 152-9 are spaced apart from the boundary lines and around the center of the corresponding first color filter 121 such that each of the first nano-light pillars 152-1 is interposed between two of the ninth nano-light pillars 152-9. The tenth nano-light pillars 152-10 are spaced apart from the boundary lines and around the center of the third color filter 123 such that the tenth nano-light pillars 152-10 surround the fifth nano-light pillar 152-5.

In some embodiments, as the color filters 121-123 are respectively divided into four regions by the symmetry axes 200 in the plan view, the centers of the four ninth nano-light pillars 152-9 within each of the first color filters 121 may be aligned with the centers of the four regions of the corresponding first color filter 121 along the Z-axis direction, respectively. Similarly, the centers of the four tenth nano-light pillars 152-10 may be aligned with the centers of the four regions of the third color filter 123 along the Z-axis direction, respectively.

When the eighth nano-light pillars 152-8, the ninth nano-light pillars 152-9, and the tenth nano-light pillars 152-10 exist in the image sensor 100o, the dimension of the tenth nano-light pillars 152-10 is larger than the dimensions of the second nano-light pillars 152-2, the eighth nano-light pillars 152-8, and the ninth nano-light pillar 152-9. The dimension of the ninth nano-light pillar 152-9 may be larger than, equal to, or smaller than the dimension of the eighth nano-light pillars 152-8. The dimension of the tenth nano-light pillar 152-10 may be larger than, equal to, or smaller than the dimension of the fifth nano-light pillars 152-5.

According to the above-mentioned embodiments, the image sensor of the present disclosure includes the nano-light pillars above the color filter array to provide hybrid function of the light scattering and the light phase controlling. The nano-light pillars are arranged in the suitable pattern depending on the color filter array, so that the light may be scattered into the specific position to manipulate the light energy received by the photodiodes below the color filters having different wavelength bands. Therefore, the image performance of the image sensor may be improved.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An image sensor, comprising:
two first color filters corresponding to a first wavelength band;
a second color filter corresponding to a second wavelength band different from the first wavelength band;
a third color filter corresponding to a third wavelength band different from the first wavelength band and the second wavelength band,
wherein the first color filters, the second color filter, and the third color filter are arranged in a color filter array of two rows by two columns, and the first color filters are diagonally disposed in the color filter array; and
a plurality of nano-light pillars above the color filter array,
wherein the plurality of the nano-light pillars, in a plan view, comprise:
two first nano-light pillars within each of the first color filters;
two second nano-light pillars on each of boundary lines between the first color filters and the second color filter;
a third nano-light pillar on each of the boundary lines between the first color filters and the second color filter;
four fourth nano-light pillars within the second color filter; and
a fifth nano-light pillar within the third color filter,
wherein a dimension of the fourth nano-light pillars and a dimension of the fifth nano-light pillar are larger than dimensions of the first nano-light pillars, the second nano-light pillars, and the third nano-light pillar.

2. The image sensor of claim 1, wherein the plurality of the nano-light pillars are spaced apart from boundary lines between the first color filters and the third color filter.

3. The image sensor of claim 1, wherein the plurality of the nano-light pillars are spaced apart from corners of the first color filters, the second color filter, and the third color filter.

4. The image sensor of claim 1, wherein a center of the fifth nano-light pillar is aligned with a center of the third color filter along a direction which is perpendicular to the plan view.

5. The image sensor of claim 1, wherein one of the first color filters is divided into four regions by a first symmetry axis and a second symmetry axis in the plan view, and the first symmetry axis intersects centers of the first nano-light pillars within the one of the first color filters.

6. The image sensor of claim 5, wherein extended lines extend through centers of each adjacent two of the four regions, and the extended lines intersect the centers of the first nano-light pillars within the one of the first color filters.

7. The image sensor of claim 5, wherein extended lines extend through centers of each adjacent two of the four regions, and the centers of the first nano-light pillars within the one of the first color filters are offset from the extended lines.

8. The image sensor of claim 5, wherein extended lines extend through centers of each adjacent two of the four regions, and the extended lines intersect centers of the second nano-light pillars on the boundary line between the one of the first color filters and the second color filter.

9. The image sensor of claim 5, wherein the second symmetry axis intersects a center of the third nano-light pillar on the boundary line between the one of the first color filters and the second color filter.

10. The image sensor of claim 1, wherein centers of the second nano-light pillars and the third nano-light pillar are offset from each of the boundary lines.

11. The image sensor of claim 1, wherein the second color filter is divided into four regions by a first symmetry axis and a second symmetry axis in the plan view, and centers of the fourth nano-light pillars are aligned with centers of the four regions along a direction which is perpendicular to the plan view, respectively.

12. The image sensor of claim 1, wherein the plurality of the nano-light pillars, in the plan view, further comprise:
four sixth nano-light pillars within the second color filter,
wherein the sixth nano-light pillars and the fourth nano-light pillars are alternately arranged around a center of the second color filter, and
wherein a dimension of the sixth nano-light pillars is larger than the dimension of the fourth nano-light pillars.

13. The image sensor of claim 12, wherein the second color filter is divided into four regions by a first symmetry axis and a second symmetry axis in the plan view, extended lines extend through centers of each adjacent two of the four regions, and centers of the fourth nano-light pillars and the sixth nano-light pillars are offset from the extended lines.

14. The image sensor of claim 12, wherein the plurality of the nano-light pillars, in the plan view, further comprise:
a seventh nano-light pillar within the second color filter, wherein a center of the seventh nano-light pillar is aligned with the center of the second color filter along a direction which is perpendicular to the plan view.

15. The image sensor of claim 14, wherein the plurality of the nano-light pillars, in the plan view, further comprise:
an eighth nano-light pillar on each of junction corners between the first color filters, the second color filter, and the third color filter.

16. The image sensor of claim 14, wherein the plurality of the nano-light pillars, in the plan view, further comprise:
four ninth nano-light pillars within each of the first color filters and around a center of each of the first color filters;
four tenth nano-light pillars within the third color filter and around a center of the third color filter; and
an eleventh nano-light pillar within each of the first color filters, wherein a center of the eleventh nano-light pillar is aligned with the center of each of the first color filters along the direction which is perpendicular to the plan view,
wherein the dimension of the fifth nano-light pillar is larger than a dimension of the eleventh nano-light pillar, and
wherein a dimension of the tenth nano-light pillars is larger than a dimension of the ninth nano-light pillars.

17. The image sensor of claim 12, wherein the plurality of the nano-light pillars, in the plan view, further comprise:
an eighth nano-light pillar on each of junction corners between the first color filters, the second color filter, and the third color filter.

18. The image sensor of claim 1, wherein the plurality of the nano-light pillars, in the plan view, further comprise:
an eighth nano-light pillar on each of junction corners between the first color filters, the second color filter, and the third color filter;
four ninth nano-light pillars within each of the first color filters and around a center of each of the first color filters; and
four tenth nano-light pillars within the third color filter and around a center of the third color filter,
wherein a dimension of the tenth nano-light pillars is larger than the dimension of the second nano-light pillars, a dimension of the eighth nano-light pillar, and a dimension of the ninth nano-light pillar.

19. The image sensor of claim 1, wherein one of the plurality of the nano-light pillars has a first dimension in a range of 60 nm to 200 nm, and another one of the plurality of the nano-light pillars has a second dimension in a range of 200 nm to 600 nm.

20. The image sensor of claim 1, wherein the first color filters are two green color filters or two clear color filters, the second color filter is a red color filter, and the third color filter is a blue color filter.
